(19) United States
(12) Patent Application Publication
(10) Pub. No.: US 2018/0287835 A1
(43) Pub. Date: Oct. 4, 2018

(54) RADIO FREQUENCY FRONT-END SLEW AND JITTER CONSISTENCY FOR VOLTAGES BELOW 1.8 VOLTS

(71) Applicant: QUALCOMM Incorporated, San Diego, CA (US)

(72) Inventors: Lalan Jee MISHRA, San Diego, CA (US); Helena Deirdre O'SHEA, San Diego, CA (US); Chiew-Guan TAN, San Diego, CA (US); ZhenQi CHEN, Shirley, MA (US); Wilson Jianbo CHEN, San Diego, CA (US); Richard Dominic WIETFELDT, San Diego, CA (US)

(21) Appl. No.: 15/920,270

(22) Filed: Mar. 13, 2018

Related U.S. Application Data
(60) Provisional application No. 62/481,315, filed on Apr. 4, 2017.

(51) Int. Cl. H04L 27/00; H03K 3/011; H03K 5/01; H04B 3/46; H04B 3/06; H04L 25/02; H04L 25/03; H04L 29/06

(52) U.S. Cl. CPC H04L 27/0002; H03K 3/011; H03K 5/01; H04L 69/03; H04B 3/06; H04L 25/0286; H04L 25/03834; H04B 3/46

(57) ABSTRACT

Systems, methods, and apparatus for managing digital communication interfaces coupled to data communication links are disclosed. In one example, the digital communication interfaces provide methods, protocols and techniques that may be used to provide a common slew rate for signals transmitted on a communication link that may be operated at multiple different voltage ranges. A method may include determining a first voltage range defined for transmitting signals over the communication link when the over the communication link is operated in a first mode of operation, configuring a line driver to operate within the first voltage range with a common slew rate that applies to each of a plurality of modes of operation, and transmitting first data over the communication link in one or more signals that switch within the first voltage range with the common slew rate. Each mode of operation may define a different voltage range for transmitting signals.

### CROSS-REFERENCE TO RELATED APPLICATIONS

This application claims priority to and the benefit of Provisional Patent Application No. 62/481,315 filed in the U.S. Patent Office on Apr. 4, 2017, the entire content of which is incorporated herein by reference as if fully set forth below in its entirety and for all applicable purposes.

### TECHNICAL FIELD

The present disclosure relates generally to communications links connecting integrated circuit devices within an apparatus, and more particularly, to signaling specifications for different process technologies employed in integrated circuit devices.

### BACKGROUND

A mobile communications apparatus may include integrated circuit (IC) devices that use high-speed digital interconnects to communicate between or within certain IC devices. For example, a cellular telephone may include high-speed digital interconnects to support communication between radio frequency (RF) and baseband modem chipsets. High-speed digital interconnects may be used to transport data, control information or both data and control information between different functional components of an apparatus. Serial interfaces have become the preferred method for digital communication between IC devices in various apparatus. For example, a communications apparatus may use a high speed digital interconnect between RF and baseband modem chipsets. Mobile communications devices may perform certain functions and provide capabilities using IC devices that include RF transceivers, cameras, display systems, user interfaces, controllers, storage, and the like. Serial interfaces known in the industry include interfaces defined by the Mobile Industry Processor Interface (MIPI) Alliance, such as the radio frequency front-end (RFFE) interface and the I3C interface. Some standardized interfaces and proprietary interfaces may be applicable for use in coupling certain components of mobile communications equipment and may be optimized to meet certain requirements of the mobile communications equipment.

In one example, the RFFE interface defines a communication interface for controlling various radio frequency front-end devices, including power amplifier (PA), low-noise amplifiers (LNAs), antenna tuners, filters, sensors, power management devices, switches, etc. These devices may be collocated in a single integrated circuit (IC) or provided in multiple IC devices. In a mobile communications device, multiple antennas and radio transceivers may support multiple concurrent RF links. Certain functions can be shared among the front-end devices and the RFFE interface enables concurrent and/or parallel operation of transceivers using multi-master, multi-slave configurations.

Device manufacturing technology continues to improve, and operational characteristics of communication interfaces may be affected by improvements in process technology. For example, protocols defining the timing of signals can be affected when operating voltages in IC devices are lowered. In the example of an RFFE interface, strict timing specifications are defined for signaling between devices. There is a continuing need to improve the RFFE interface to accommodate the adoption of improved process technology.

### SUMMARY

Certain aspects of the disclosure relate to systems, apparatus, methods and techniques for implementing and managing digital communication interfaces that may be used between IC devices in various apparatus. In some aspects, the digital communication interfaces provide methods, protocols and techniques that may be used to provide a common slew rate for signals transmitted on a communication link that may be operated at multiple different voltage ranges.

In various aspects of the disclosure, a method for controlling transmissions by a device coupled to a communication link may include determining a first voltage range defined for transmitting signals over the communication link when the over the communication link is operated in a first mode of operation, configuring a line driver to operate within the first voltage range with a common slew rate that applies to each of a plurality of modes of operation, and transmitting first data over the communication link in one or more signals that switch within the first voltage range with the common slew rate. Each mode of operation may define a different voltage range for transmitting signals on the communication link.

In some aspects, configuring the line driver to operate within the first voltage range includes determining a rise time and a fall time for the line driver by applying a scaling factor to rise and fall times specified for a baseline mode of operation. In one example, the first voltage range is 1.2 volts and a voltage range associated with the baseline mode of operation is 1.8 volts. In another example, the first voltage range is 1.0 volts and a voltage range associated with the baseline mode of operation is 1.8 volts. In another example, the first voltage range is 0.9 volts and a voltage range associated with the baseline mode of operation is 1.8 volts.

In one aspect, configuring the line driver to operate within the first voltage range includes determining an operating point characterizing process, voltage and temperature (PVT) conditions, and adjusting an output setting of the line driver based on the PVT conditions. The output setting may configure transition times for the one or more signals.

In one aspect, configuring the line driver to operate within the first voltage range includes configuring a high voltage circuit of the line driver to switch within the first voltage range when the first voltage range is lower than a rated voltage range for the high voltage circuit.

In one aspect, configuring the line driver to operate within the first voltage range includes configuring transition times for the one or more signals using a slew optimization circuit.

In some aspects, the method includes configuring the line driver to operate within a second voltage range corresponding to a second mode of operation, the second voltage range being different from the first voltage range, and transmitting second data over the communication link in one or more signals that switch within the second voltage range with the common slew rate. In one example, configuring the line driver to operate within the first voltage range includes determining transition times for the one or more signals by applying a scaling factor to rise and fall times specified for the second mode of operation. In another example, configuring the line driver to operate within the first voltage range includes configuring a high voltage circuit of the line driver to switch within the first voltage range when the first voltage range is lower than the second voltage range and when the high voltage circuit is rated for the second voltage range. In another example, configuring the line driver to operate within a selected mode of operation includes configuring transition times for the one or more signals using a slew optimization circuit.

In various aspects of the disclosure, an apparatus includes an output driver, at least one pre-driver circuit coupled to the output driver, and a slew rate control circuit adapted to configure transition times for an output signal provided by the output driver. The output driver may be operable in plurality of modes, each mode defining a different voltage range of the output signal. The output driver may be adapted such that transitions in the output signal have a common slew rate for each voltage range defined by the plurality of modes.

In one aspect, the apparatus includes a compensation circuit configured to define a rise time and a fall time for the output signal by applying a scaling factor to rise and fall times specified for a baseline mode.

In one aspect, the apparatus includes a compensation circuit adapted to configure the output driver and the at least one pre-driver circuit based on PVT conditions.

In one aspect, the output driver is rated to switch within a first voltage range, and the apparatus includes a compensation circuit adapted to configure the output driver to switch within a second voltage range when the second voltage range is lower than the first voltage range. The output driver may be adapted to provide the common slew rate when the output driver switches within the first voltage range and when the output driver switches within the second voltage range.

In various aspects of the disclosure, an apparatus may have means for determining a first voltage range defined for transmitting signals over the communication link when the over the communication link is operated in a first mode of operation, means for configuring a line driver to operate within the first voltage range with a common slew rate that applies to each of a plurality of modes of operation, and means for transmitting first data over the communication link in one or more signals that switch within the first voltage range with the common slew rate. Each mode of operation may define a different voltage range for transmitting signals on the communication link.

In various aspects of the disclosure, a processor readable storage medium is disclosed. The storage medium may be a non-transitory storage medium and may store code that, when executed by one or more processors, causes the one or more processors to determine a first voltage range defined for transmitting signals over the communication link when the over the communication link is operated in a first mode of operation, configure a line driver to operate within the first voltage range with a common slew rate that applies to each of a plurality of modes of operation, and transmit first data over the communication link in one or more signals that switch within the first voltage range with the common slew rate. Each mode of operation may define a different voltage range for transmitting signals on the communication link.

### BRIEF DESCRIPTION OF THE DRAWINGS

FIG. 1 illustrates an apparatus that includes a processing circuit having multiple circuits or devices and that may be adapted in accordance with certain aspects disclosed herein.

FIG. 2 illustrates a first example in which a high-speed bus is provided in a device that may be adapted according to certain aspects disclosed herein.

FIG. 3 illustrates a second example in which a high-speed bus is provided in a device that may be adapted according to certain aspects disclosed herein.

FIG. 4 illustrates timing corresponding to drivers that operate at 1.8 volts and 1.2 volts according to RFFE specifications.

FIG. 5 illustrates timing corresponding to a driver that operates at 1.8 volts according to RFFE specifications, and a driver fabricated for operation at 1.2 volts in accordance with certain aspects disclosed herein.

FIG. 6 is a timing diagram illustrating the effect of an adjustment in slew rate for 1.2-volt drivers in accordance with certain aspects disclosed herein.

FIG. 7 illustrates a generalized specification for driver operation in accordance with certain aspects disclosed herein.

FIG. 8 illustrates a conventional specification for rise time, fall time and slew rate.

FIG. 9 illustrates scaling factors used to modify rise time and fall time in order to maintain a consistent skew rate across different operating voltages in accordance with certain aspects disclosed herein.

FIG. 10 illustrates rise time and fall time specifications for different input/output voltage (VIO) at standard frequency.

FIG. 11 illustrates a process that may be implemented in an I/O pad circuit of a dual voltage-mode driver.

FIG. 12 illustrate examples of circuits implemented in an I/O pad circuit of a dual voltage-mode driver in accordance with certain aspects disclosed herein.

FIG. 13 illustrates a further example of a circuit implemented in an I/O pad circuit of a dual voltage-mode driver in accordance with certain aspects disclosed herein.

FIG. 14 illustrates an example of an apparatus employing a processing circuit that may be adapted according to certain aspects disclosed herein.

FIG. 15 is a flow chart of a first method related to synchronizing system time used by devices coupled to a data communication link in accordance with certain aspects disclosed herein.

FIG. 16 illustrates an example of a hardware implementation for a transmitting apparatus that includes a processing circuit adapted according to certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of systems will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Overview

Process technology employed to manufacture semiconductor devices, including IC devices is continually improving. Process technology includes the manufacturing methods used to make IC devices and defines transistor size, operating voltages and switching speeds. Features that are constituent elements of circuits in and IC device may be referred as technology nodes and/or process nodes.

IC devices may communicate through a communication link, where a physical conductive pad on an IC device provides a connection point through which signals may be transmitted and/or received. The term pad may refer to a physical pad and an associated driver circuit that is configured for driving a load that has a specified impedance, at specified voltage and current levels or ranges, and under specified noise levels, electrostatic discharges, and electromagnetic induction.

Systems, methods, and apparatus for managing digital communication interfaces coupled to data communication links are disclosed herein. The digital communication interfaces may be operable to provide a common slew rate for signals transmitted through I/O pads to a communication link that may be operated at multiple different voltage ranges. A method may include determining a first voltage range defined for transmitting signals over the communication link when the over the communication link is operated in a first mode of operation, configuring a line driver to operate within the first voltage range with a common slew rate that applies to each of a plurality of modes of operation, and transmitting first data over the communication link in one or more signals that switch within the first voltage range with the common slew rate. Each mode of operation may define one or more different voltage ranges for transmitting signals.

Example of an Apparatus with Multiple IC Device Subcomponents

According to certain aspects, a serial data link may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, a drone, a multicopter, or any other similar functioning device.

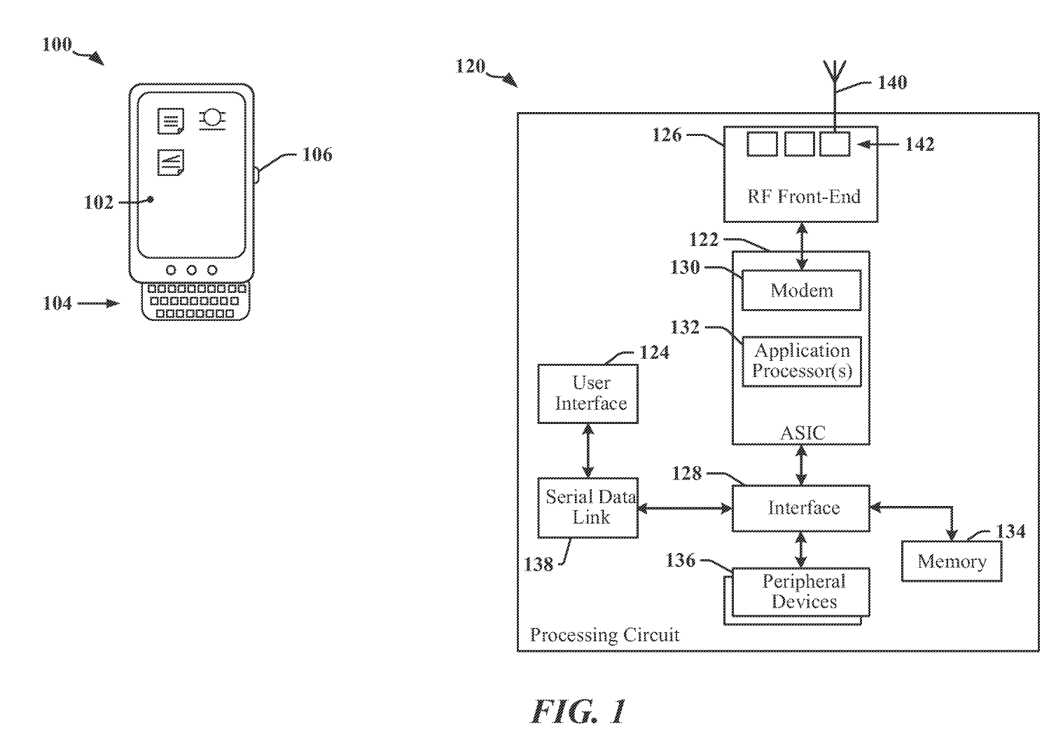

FIG. 1 depicts an example of an apparatus 100 that includes a processing circuit 120 having multiple circuits or devices 122, 124, 126, 128, 134, 136, and/or 138. The processing circuit 120 may be implemented in an ASIC or SoC that may include multiple circuits or devices 122, 124, 126, 128, 134, 136, and/or 138. In one example, the apparatus 100 may be a communication device and the processing circuit 120 may include an RF front-end device 126 that enables the apparatus to communicate through one or more antennas 140 with a radio access network, a core access network, the Internet and/or another network. The RF front-end device 126 may include a plurality of devices 142 coupled by a second communication link, which may include an RFFE bus.

In the example illustrated in FIG. 1, the processing circuit 120 includes an ASIC device 122 that has one or more processors 132, one or more modems 130, and/or other logic circuits or functions. The processing circuit 120 may be controlled by an operating system and may provide an application programming interface (API) layer that enables the one or more processors 132 to execute software modules residing in the memory device 134, for example. The software modules may include instructions and data stored in a processor readable storage such as the memory device 134. The ASIC device 122 may access its internal memory, the memory device 134 of the processing circuit 120, and/or external memory. Memory may include read-only memory (ROM) or random-access memory (RAM), electrically erasable programmable ROM (EEPROM), flash cards, or any memory device that can be used in processing systems and computing platforms. The processing circuit 120 may include, or have access to a local database or other parameter storage that can maintain operational parameters and other information used to configure and operate the apparatus 100 and/or the processing circuit 120. The local database may be implemented using registers, a database module, flash memory, magnetic media, EEPROM, optical media, tape, soft or hard disk, or the like. The processing circuit 120 may also be operably coupled to external devices such as the antenna 140, a display 102, operator controls, such as a button 106 and/or an integrated or external keypad 104, among other components. A user interface 124 may communicate with the display 102, keypad 104, etc. through a dedicated communication link 138 or through one or more serial data interconnects.

The processing circuit 120 may communicate through one or more interface circuits 128, which may include a combination of circuits, counters, timers, control logic and other configurable circuits or modules. In one example, the interface circuit 128 may be configured to operate in accordance with communication specifications or protocols. The processing circuit 120 may include or control a power management function that configures and manages the interface circuit 128, the user interface 124, the RF front-end circuit 126, and the operation of one or more application processors 132 resident in the ASIC device 122, for example.

Examples of Interfaces Coupling Devices in a Communication Device

According to certain aspects disclosed herein, an advanced digital interface may be provided between baseband and RF integrated circuits in mobile communication devices and the like. The advanced digital interface may optimize RF and baseband functions, including software and hardware functions. Device input/output pin count may be reduced, performance increased, and printed circuit board and/or chip carrier area usage minimized. The digital interface may be used to interconnect a baseband RF modem with a radio frequency integrated circuit (RFIC), providing reduced complexity of RF calibration when the baseband modem is mated with a suitable RFIC, providing an appropriate set of functions that optimizes chipset cost.

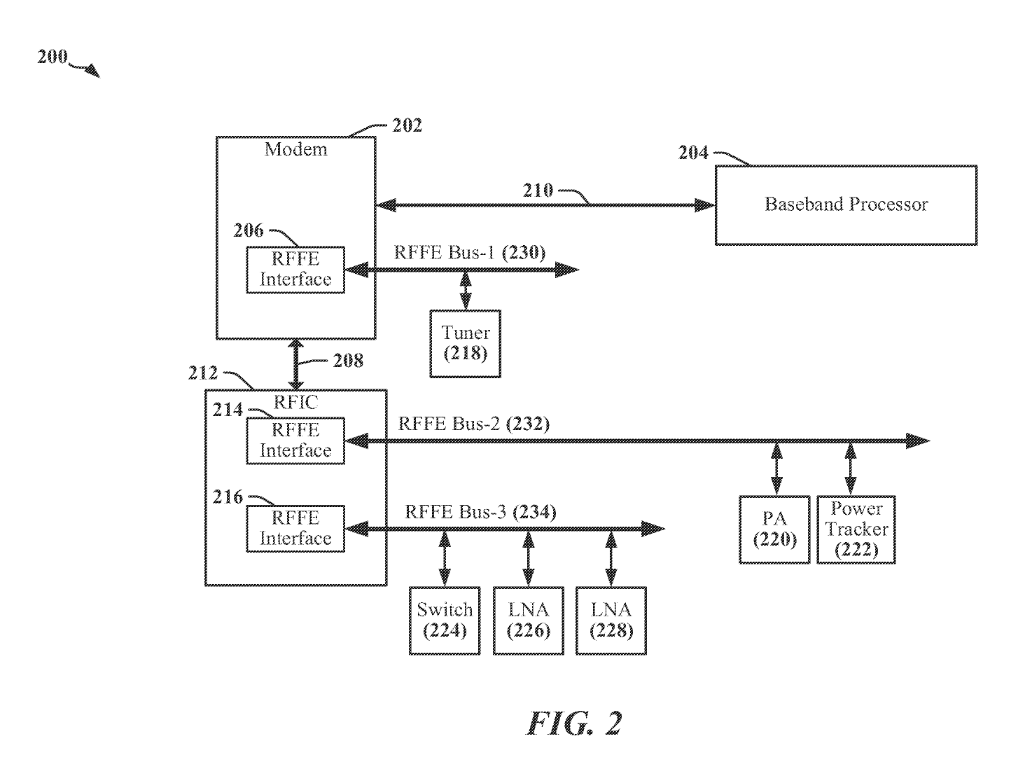

FIG. 2 illustrates a first example of a system 200 that can be implemented in a chipset, one or more SoCs and/or other configuration of devices. The system 200 employs multiple RFFE busses 230, 232, 234 that can support communication between and with various RF front-end devices 218, 220, 222, 224, 226 228. In this system 200, a modem 202 includes an RFFE interface 206 that can couple the modem 202 to a first RFFE bus 230. The modem 202 may communicate with a baseband processor 204 and an RFIC 212 through one or more communication links 208, 210. The system 200 may be embodied in one or more of a mobile communication device, a mobile telephone, a mobile computing system, a mobile telephone, a notebook computer, a tablet computing device, a media player, a gaming device, a wearable computing and/or communications device, a multicopter or other drone, an appliance, or the like.

In various examples, the system 200 may include one or more baseband processors 204, modems 202, RFICs 212, multiple communications links 210, 208, multiple RFFE buses 230, 232, 234 and/or other types of buses. The device 202 may include other types of processors, circuits, modules and/or buses. The system 200 may be configured for various operations and/or different functionalities. In the system 200 illustrated in FIG. 2, the Modem is coupled to an RF tuner 218 through its RFFE interface 206 and the first RFFE bus 230. The RFIC 212 may include one or more RFFE interfaces 214, 216, controllers, state machines and/or processors that configure and control certain aspects of the RF front-end. The RFIC 212 may communicate with a PA 220 and a power tracking module 222 through a first of its RFFE interfaces 214 and the second RFFE bus 232. The RFIC 212 may communicate with a switch 224 and one or more LNAs 226, 228 through a second of its RFFE interfaces 216 and the third RFFE bus 234.

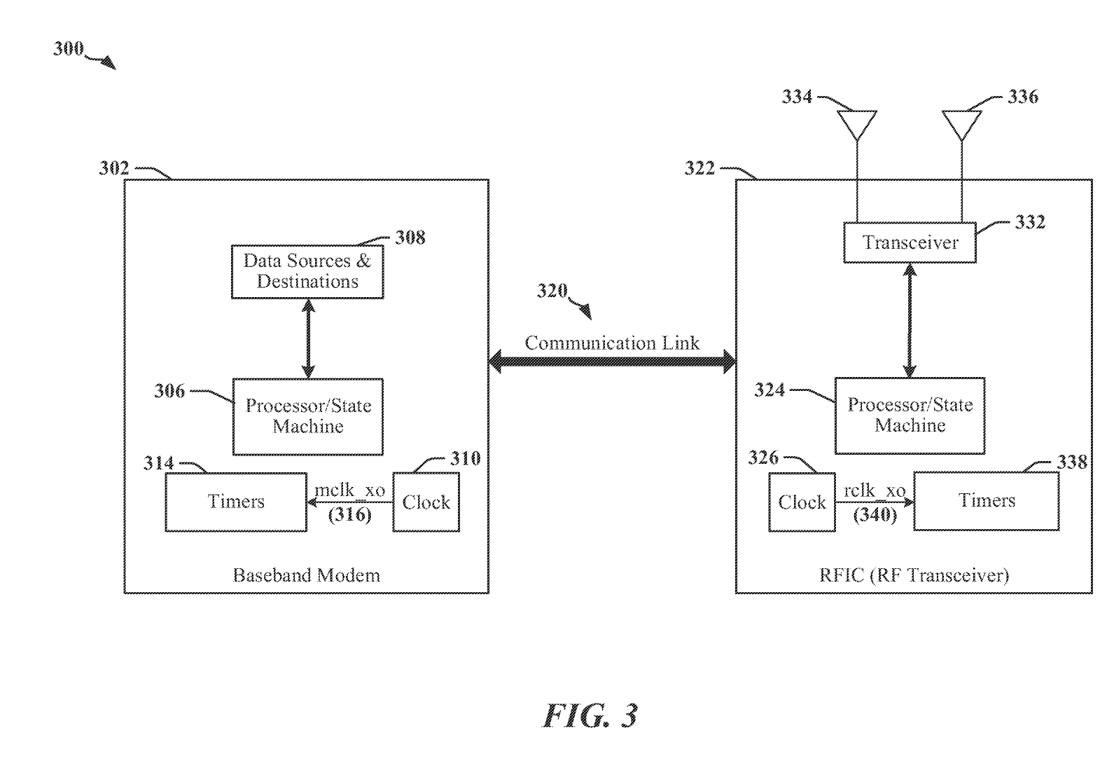

FIG. 3 illustrates a second example in which a communication link 320 is provided in an apparatus 300 that may be adapted according to certain aspects disclosed herein. The communication link 320 may be operated in accordance with RFFE specifications and/or protocols, and may be configured to couple a baseband modem 302 with an RFIC 322. FIG. 3 illustrates certain features and elements associated with the operation of the communication link 320 and may include other components including processors, storage, logic, etc.

The baseband modem 302 may include a state machine or processor 306 that controls communication over the communication link 320. Information communicated over the communication link 320 may be stored in buffers between the communication link 320 and data sources or destinations 308. The baseband modem 302 may include other circuits and modules associated with the communication link 320 and clock generation, extraction and synchronization circuits 310.

The RFIC 322 may include a state machine or processor 324 that controls communication over the communication link 320. Information communicated over the communication link 320 may be stored in buffers between the communication link 320 and an RF transceiver 332. The RF transceiver 332 may be configured to communicate through one or more antennas 334, 336. The RFIC 322 may include other circuits and modules associated with the communication link 320, including error checking/correction circuits or modules, timers 338, and clock generation, extraction and synchronization circuits 326.

Transmitting Signals on a Communication Link

Standards and/or protocols that govern operation of a communication link may define electrical characteristics and tolerances and may prescribe timing specifications affecting transitions between signaling voltage levels. As the size of process node shrinks in the semiconductor industry, significant stress is placed on input/output (I/O) pad design. In particular, designers may strive to meet current performance specifications without adding significant overhead when lower geometries are employed. In one example, existing 1.8V VIO specifications for RFFE bus may cause issues when applied to 1.2V operation.

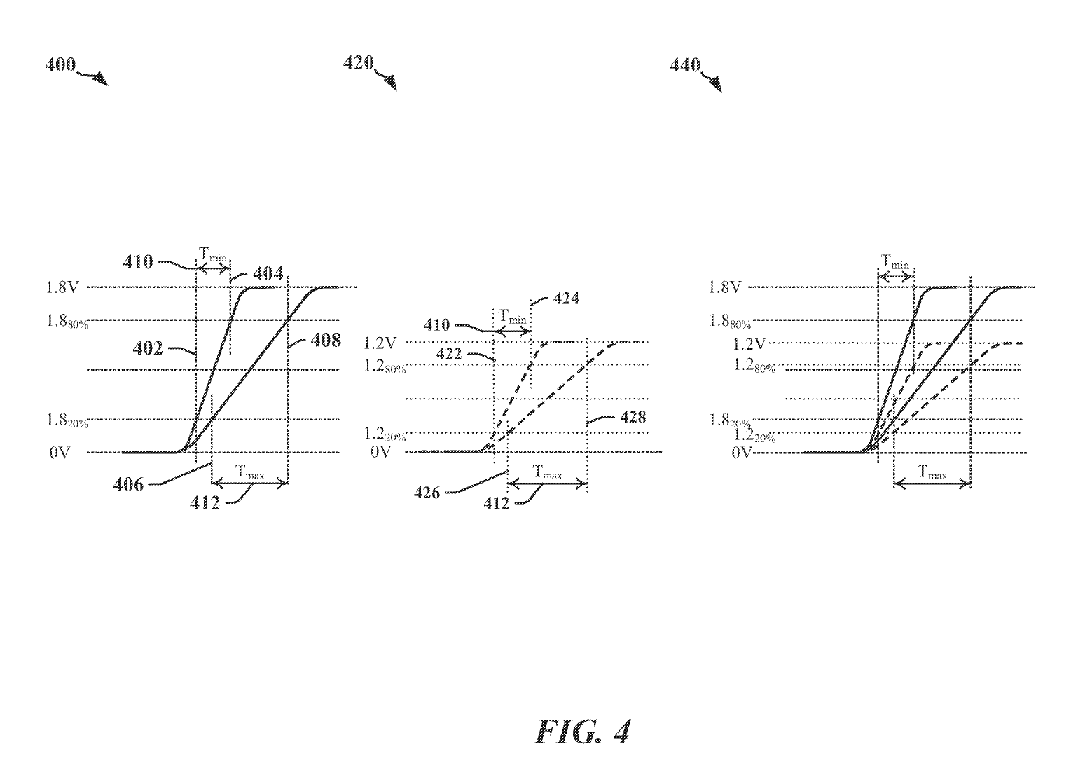

FIG. 4 includes a first timing diagram 400 corresponding to a driver that operates at 1.8 volts according to RFFE specifications, and a second timing diagram 420 corresponding to a driver fabricated for operation at 1.2 volts when the same RFFE specifications are followed. A difference in slew rate is apparent in the timing diagrams 400, 420. A third timing diagram 440 overlays the first timing diagram 400 and the second timing diagram 420.

In the first timing diagram 400, the interface operates at 1.8 volts and a faster driver provides a signal that passes through a 20% threshold at a first time 402 and through the 80% threshold at a second time 404, where the period between the first time 402 and the second time 404 is equal to the minimum transition time 410 defined by link specifications. A slower driver provides a signal that passes through a 20% threshold at a third time 406 and through the 80% threshold at a fourth time 408, where the period between the third time 406 and the fourth time 408 is equal to the maximum transition time 412 defined by link specifications.

In the second timing diagram 420, the interface operates at 1.2 volts and a faster driver provides a signal that passes through a 20% threshold at a first time 422 and through the 80% threshold at a second time 424, where the period between the first time 422 and the second time 424 is equal to the minimum transition time 410 defined by link specifications, which also applies to 1.8-volt operation. A slower driver provides a signal that passes through a 20% threshold at a third time 426 and through the 80% threshold at a fourth time 428, where the period between the third time 426 and the fourth time 428 is equal to the maximum transition time 412 defined by link specifications.

To meet the minimum transition time 410 in a 1.2-volt interface, the slew rate in a 1.2-volt interface is less than the slew rate in a 1.8-volt interface. Decreased slew rate can result in increased jitter, and can reduce the maximum data rate attainable over the communication link.

Certain aspects disclosed herein address rise time (Tᵣᵢₛₑ) and fall time (T_{fall}) issues that may arise when timing defined by the RFFE specification is applied to 1.2-volt mode of operation. Certain techniques disclosed herein can be generalized and applied to any lower operating voltage. In certain embodiments, drivers in a master device may be adapted in a manner that improves master device signaling and is transparent to slave devices.

In certain aspects, the rise time of a lower voltage driver may be modified to maintain a consistent slew rate with respect to the minimum rise time defined for both Tᵣᵢₛₑ and T_{fall} in a 1.8-volt baseline device. The technique may be applied to 1.2-volt, 1-volt, 0.9-volt and other lower voltage devices. The technique may be applied for other baseline voltages. For example, timing may be modified based on a 1.2-volt baseline, a 1-volt baseline, etc.

In one example, the minimum values for Tᵣᵢₛₑ and T_{fall} of an I/O driver may be linearly scaled with the operating voltage of the I/O driver. A common minimum-maximum range for Tᵣᵢₛₑ and T_{fall} may be maintained to keep slew rate consistent across process technologies.

At lower operating voltages, reduction in Tᵣᵢₛₑ and T_{fall} of an I/O driver may be kept within a range to avoid violating electromagnetic interference (EMI) limits for RF harmonics in the frequency band of interest for the link.

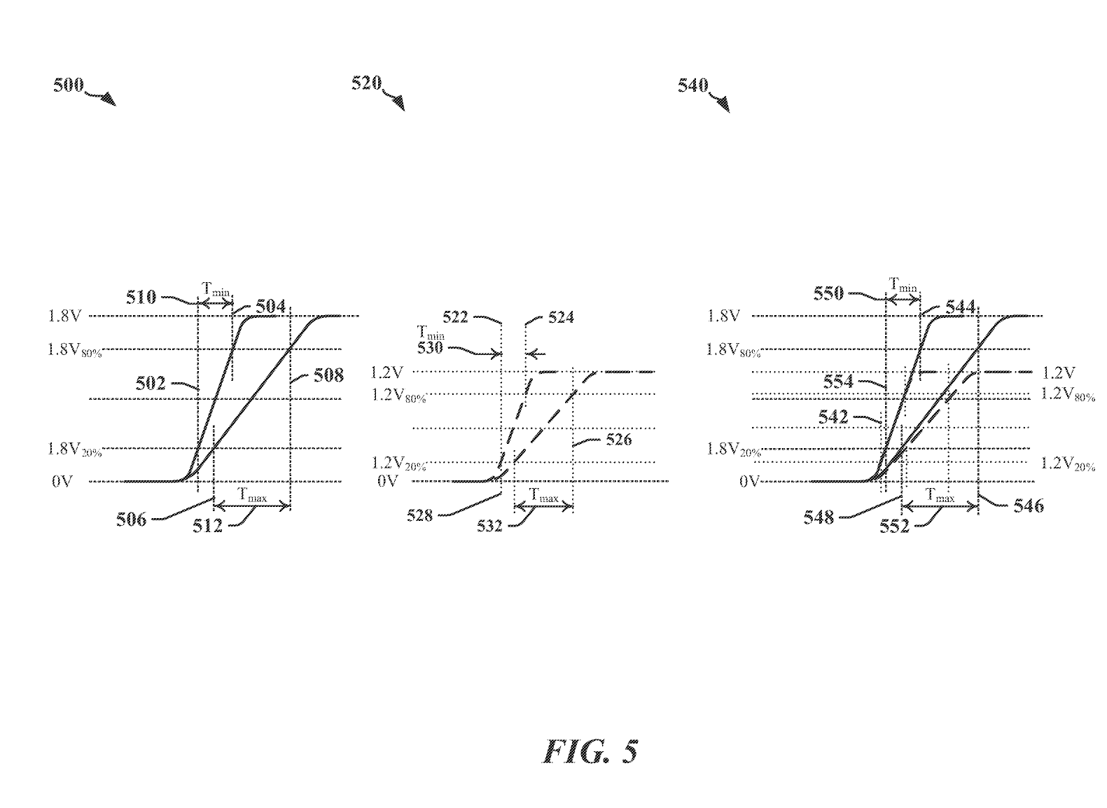

FIG. 5 illustrates a first timing diagram 500 corresponding to a driver that operates at 1.8 volts according to RFFE specifications, and a second timing diagram 520 corresponding to a driver fabricated for operation at 1.2 volts in accordance with certain aspects disclosed herein. The driver may be incorporated in the modem 202 or in an RF front-end device 212-216 (see FIG. 2), for example. Slew rate is maintained between the two process technologies as illustrated by the timing diagrams 500, 520 and by the third timing diagram 540, which overlays the first timing diagram 500 and the second timing diagram 520.

In the first timing diagram 500, the interface operates at 1.8 volts and a faster driver provides a signal that passes through a 20% threshold at a first time 502 and through the 80% threshold at a second time 504, where the period between the first time 502 and the second time 504 is equal to the minimum transition time 510 defined by link specifications. A slower driver provides a signal that passes through a 20% threshold at a third time 506 and through the 80% threshold at a fourth time 508, where the period between the third time 506 and the fourth time 508 is equal to the maximum transition time 512 defined by link specifications.

In the second timing diagram 520, the interface operates at 1.2 volts and a faster driver provides a signal that passes through a 20% threshold at a first time 522 and through the 80% threshold at a second time 524, where the period between the first time 522 and the second time 524 is equal to a minimum transition time 530 that may be different from the minimum transition time 510 defined by link specifications for 1.8-volt operation. A slower driver provides a signal that passes through a 20% threshold at a third time 526 and through the 80% threshold at a fourth time 528, where the period between the third time 526 and the fourth time 528 is equal to the maximum transition time 512 defined by link specifications.

A driver fabricated using a lower-voltage process technology may be adapted to have a slew rate that is consistent with existing specifications. A slave device may be unaffected when a driver in the master device is adapted to provide a consistent slew rate. The slave device may operate with the setup and hold specifications defined by the baseline specification.

In some implementations, a master device that can operate at multiple voltages, and may be adapted to produce the same slew rate over all voltages. A similar jitter can be budgeted in the design independently of voltage when a common slew rate is used in multiple voltage ranges.

Certain techniques disclosed herein are applicable to voltage levels that are lower than currently specified voltage ranges for RFFE. Specifications for lower voltage modes in an RFFE interface can be derived accordingly. EMI scales as expected with voltage, with only minor impact of changes in Tᵣᵢₛₑ and T_{fall} minimum values. Greater tolerance for jitter is enabled when technology is migrated from 1.8 volts to 1.2 volts when skew rate is maintained.

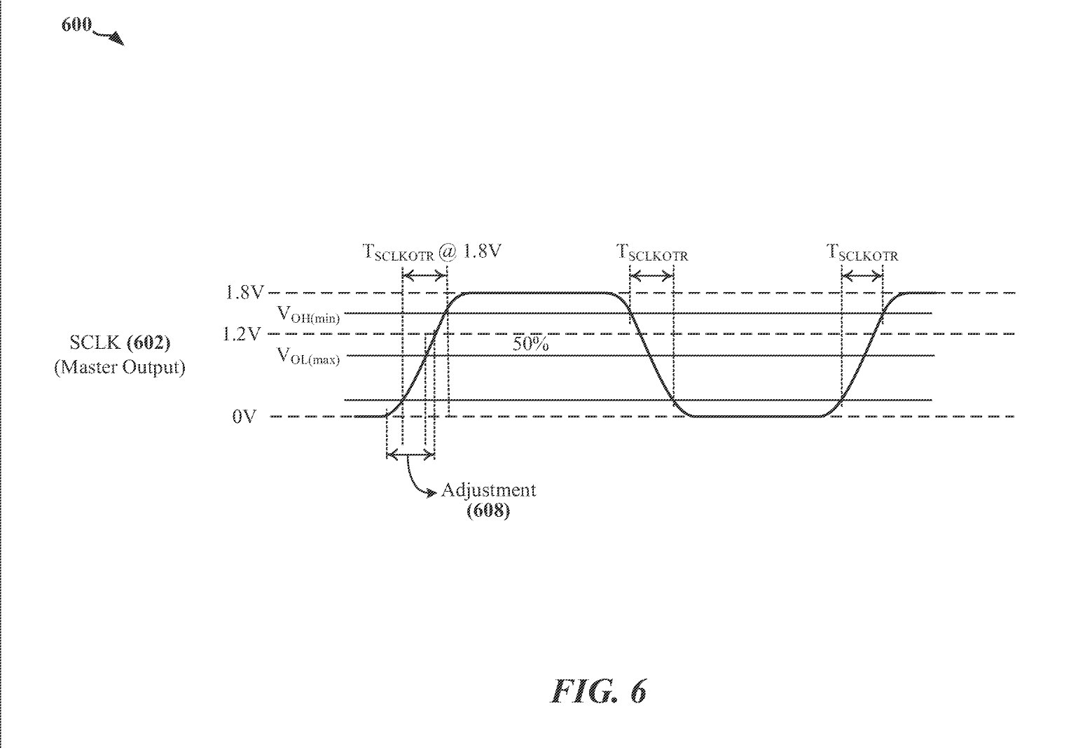

FIG. 6 is a timing diagram 600 illustrating the effect of an adjustment 608 in slew rate for 1.2-volt drivers, and the correspondence between 1.8-volt and 1.2-volt drivers. Conventionally, the RFFE specification assumes that the same timing budget applies to 1.8-volt and 1.2-volt drivers. According to certain aspects disclosed herein, an adjustment 608 is made to Tᵣᵢₛₑ and T_{fall} minimum values for a 1.2-volt driver, while maintaining the same range for a 1.8-volt driver. Slew rate may be maintained for other operating voltages, including for 1-volt and 0.9-volt process technologies. For each selected operating voltage, the slew rate for 1.8-volt operation can be maintained for the lower voltage operations. Consistent slew rate ensures signal integrity can be maintained.

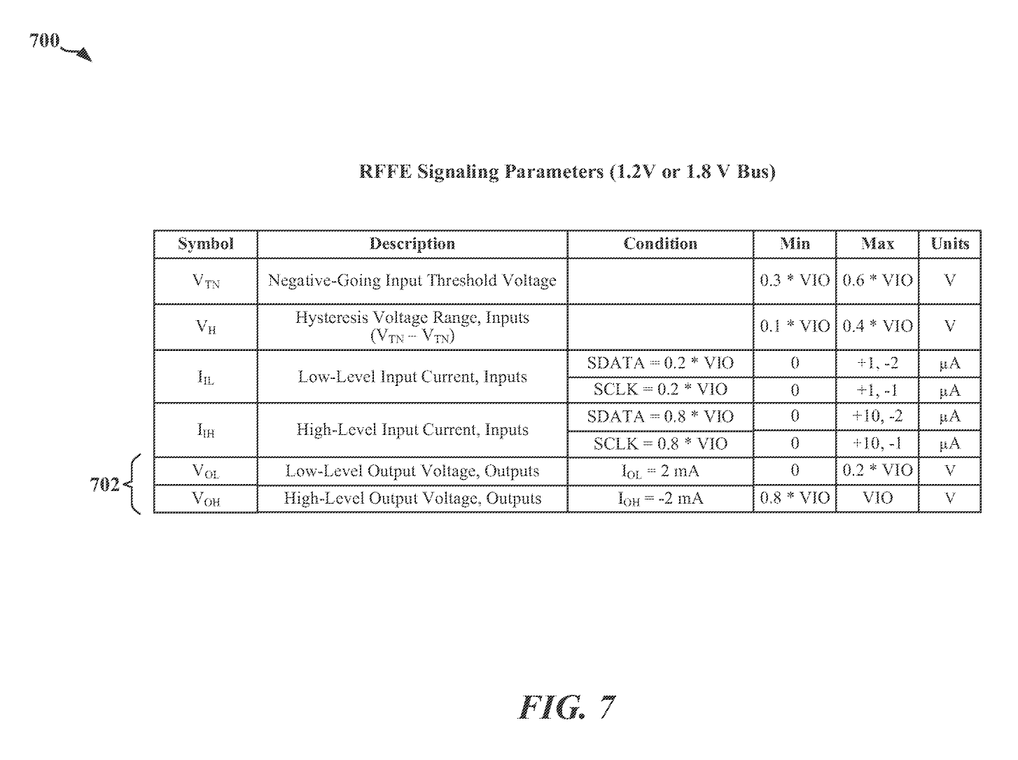

FIG. 7 illustrates a generalized specification 700 for driver operation. For example, the V_{OL}_{_}_{Max} and V_{OH}_{_}_{Min} values are defined as 20% and 80% of VIO. As illustrated in the two bottom rows 702, VOL and VOH follow the same scaling factors to define voltage levels. The specification 700 may also accommodate a 1.0-volt bus.

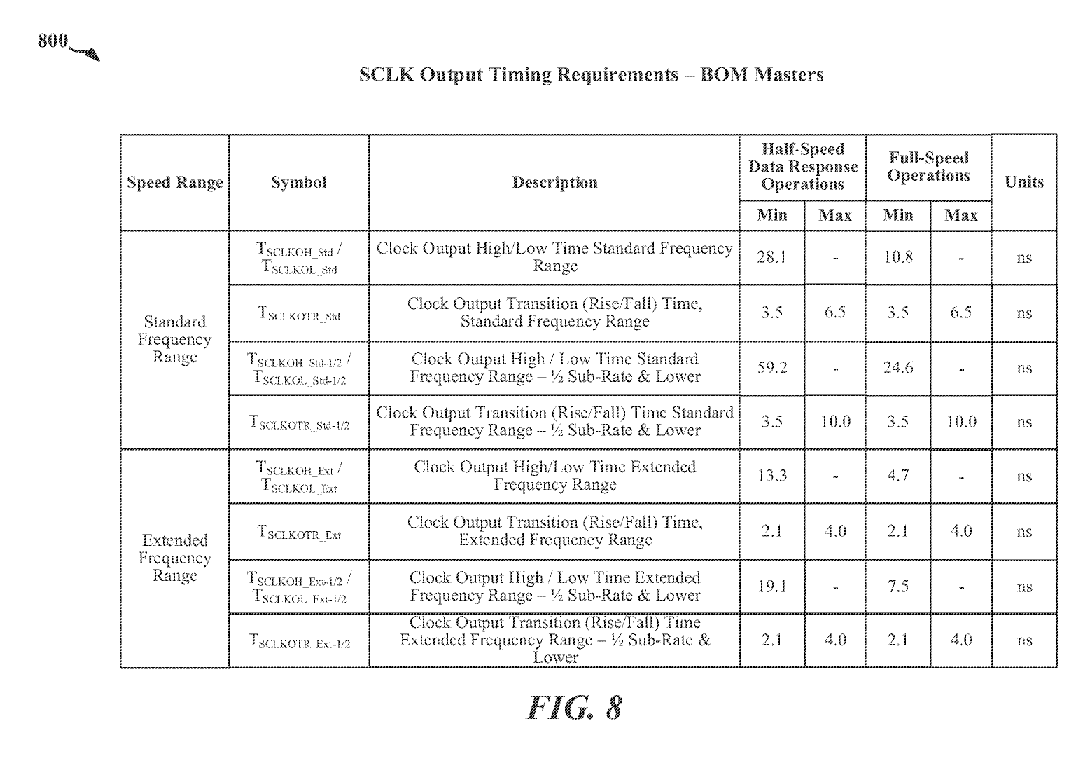

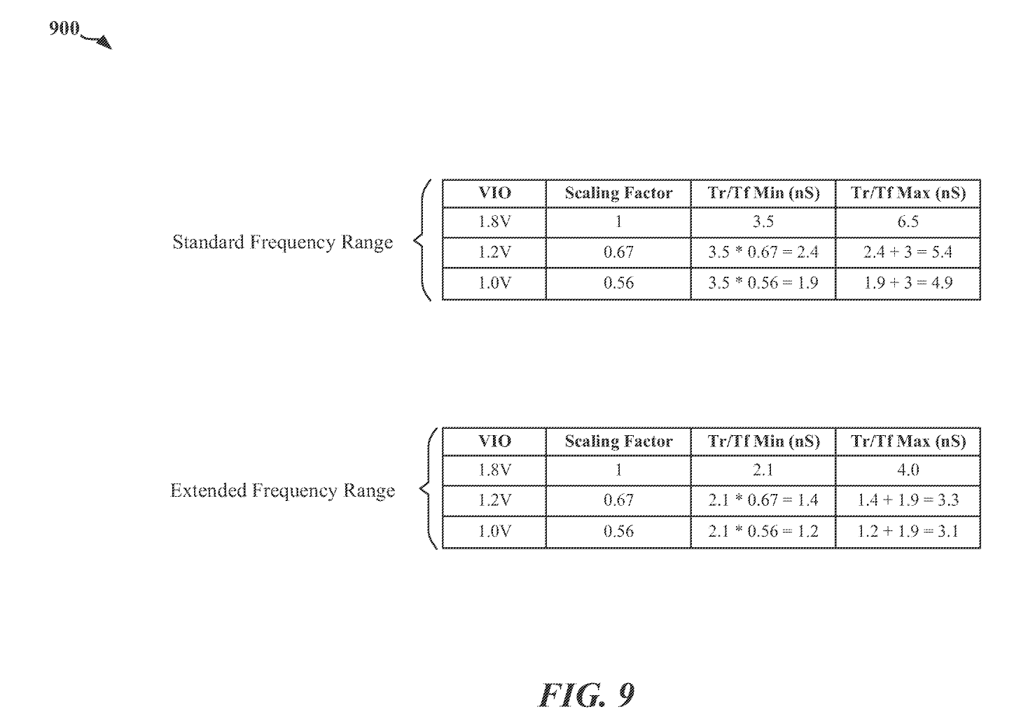

FIG. 8 illustrates a conventional specification 800 for Tᵣᵢₛₑ and T_{fall} values and for slew rate. FIG. 9 illustrates tables 900 that provide scaling factors used to modify Tᵣᵢₛₑ and T_{fall} values to maintain a consistent skew rate across different operating voltages. Taking 1.8 volts as the reference in the specification 800, a linear scaling factor may be applied to the minimum Tᵣᵢₛₑ and T_{fall} values to maintain a fixed slew rate. The maximum value of the Tᵣᵢₛₑ and T_{fall} values can be determined to have a fixed offset from the minimum Tᵣᵢₛₑ and T_{fall} values, consistent with the offset in a 1.8-volt specification. In one example, the scaling factor may be calculated as:

$$Scaling factor = \frac{{V}_{Lower}}{1.8} .$$

Dual Voltage-Mode Operation

Conventional RFFE specifications assume a common T_{RISE}/T_{FALL} value for both 1.8-volt and 1.2-volt operations. As designs migrate to lower process nodes, RFFE operation at lower VIO (1.2-volt and 1.0-volt) the 1.8-volt is no longer viable. The ecosystem evolution from 1.8 volts to 1.2 volts may also necessitate that certain devices support dual-voltage modes of operation. Additional timing window for the master device jitter budget may be required, and this may further impact master pad complexity based on the conventional specification.

The use of existing specifications for T_{RISE} and T_{FALL} values effectively reduces slew-rate. Slew rate reduction can increase signaling jitter, and increased jitter may impact master pad complexity to meet the same budget as at 1.8-volt operation.

As disclosed herein, maintaining the same T_{RISE} and T_{FALL} values for 1.8-volt, 1.2-volt and 1.0-volt operation effectively increases the slew rate range. For example, the slew rate increases from the minimum time value for 1.8-volt operation to the maximum time value for 1.2-volt and/or 1.0-volt operation.

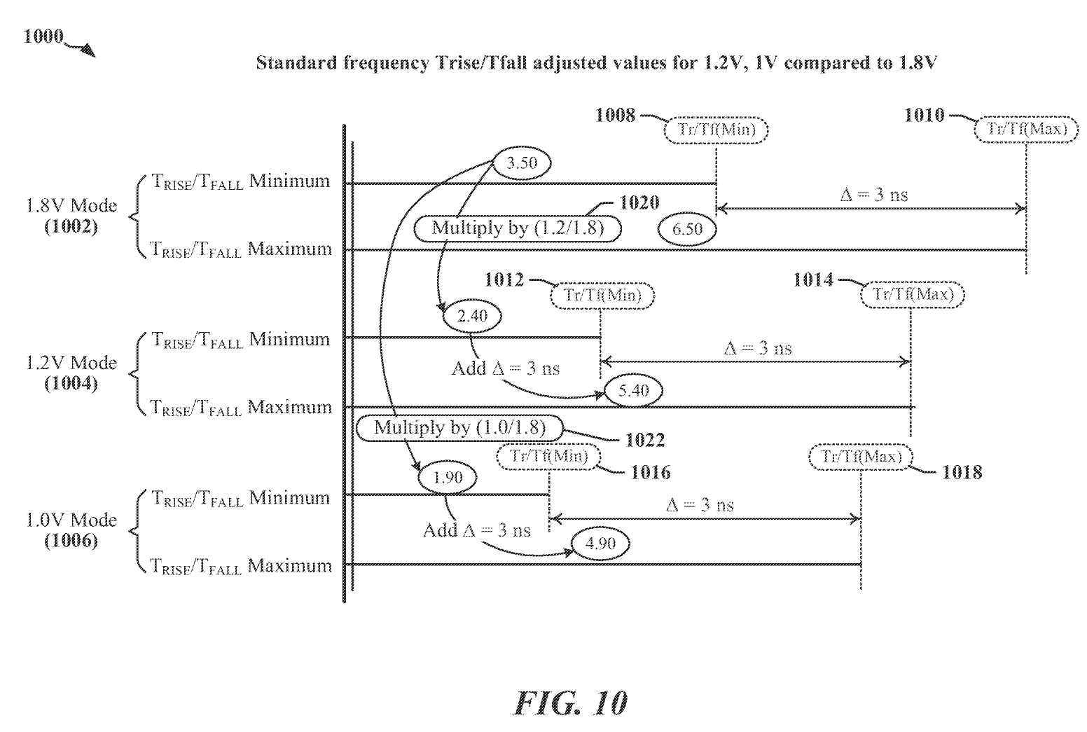

FIG. 10 illustrates rise time and fall time specifications for different VIO at standard operating frequency. In the example of 1.8V mode operation 1002, the minimum rise and fall times 1008 is 3.5 ns and the maximum rise and fall times 1010 is 3 ns longer at 6.5 ns. In the example of 1.2V mode operation 1004, the minimum rise and fall times 1012 is 2.4 ns and the maximum rise and fall times 1014 is 3 ns longer at 5.4 ns. In the example of 1.0V mode operation 1006, the minimum rise and fall times 1016 is 1.9 ns and the maximum rise and fall times 1018 is 3 ns longer at 4.9 ns. Taking 1.8V mode operation 1002 as a baseline, the maximum rise and fall times 1012, 1016 for 1.2V mode operation 1004 and 1.0V mode operation 1006, respectively, may be configured using scaling factors 1020, 1022, while the difference between maximum rise and fall times 1008, 1012, 1016 and minimum rise and fall times 1010, 1014, 1018 remains constant at 3 ns. The scaling factor 1020 between 1.8V mode operation 1002 and 1.2V mode operation 1004 is 1.2/1.8, or 2/3. The scaling factor 1022 between 1.8V mode operation 1002 and 1.0V mode operation 1006 is 1.0/1.8.

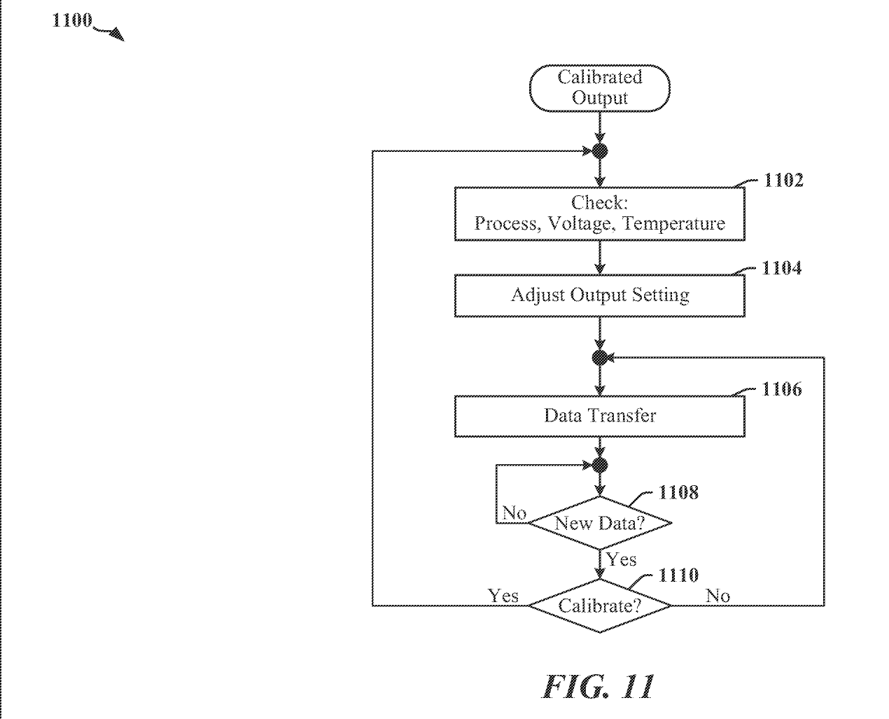

FIG. 11 illustrates a process 1100 that may be implemented in an I/O pad circuit of a dual voltage-mode driver. The dual voltage-mode driver may be incorporated in the modem 202 or in an RF front-end device 212-216 (see FIG. 2), for example. The pad circuit may be configured to support both higher and lower VIO with slew control. The pad circuit includes a calibration circuit that can be used to adjust one or more functional elements of the driver to control slew variation over process, voltage and temperature (PVT) variations. At block 1102, the pad circuit may determine process, voltage and temperature parameters from either local memory on the baseband modem or RFIC or be configured by software. At block 1104, the pad circuit may adjust one or more settings related to the output driver, before transferring data at block 1106.

At block 1108, after transmitting available data, the pad circuit may be idle until new data is detected for transfer at block 1108. In some instances, the pad circuit, or a processor associated or coupled to the pad circuit may consider whether recalibration is needed at block 1110. In other instances, block 1110 may be bypassed and the data may be transmitted without recalibration, whereby the pad circuit, or a processor associated or coupled to the pad circuit may independently determine when recalibration is needed. In still other instances, block 1110 may be bypassed and recalibration is performed before each new data transmission.

At block 1110, the pad circuit, or a processor associated or coupled to the pad circuit may determine whether a recalibration is needed or desired. When a recalibration is needed or desired, the process returns to block 1102. Otherwise, data transmission is initiated at block 1106.

In one example, the pad circuit may be configured to adjust settings by an external processor. An I/O pad circuit designed for higher VIO can be re-used for lower VIO. The process 1100 may be implemented using some combination of hardware circuits and software in order to optimize circuit complexity, system implementation, area consumed on the IC device, static current and level of software sequencing needed to calibrate the I/O pad circuit.

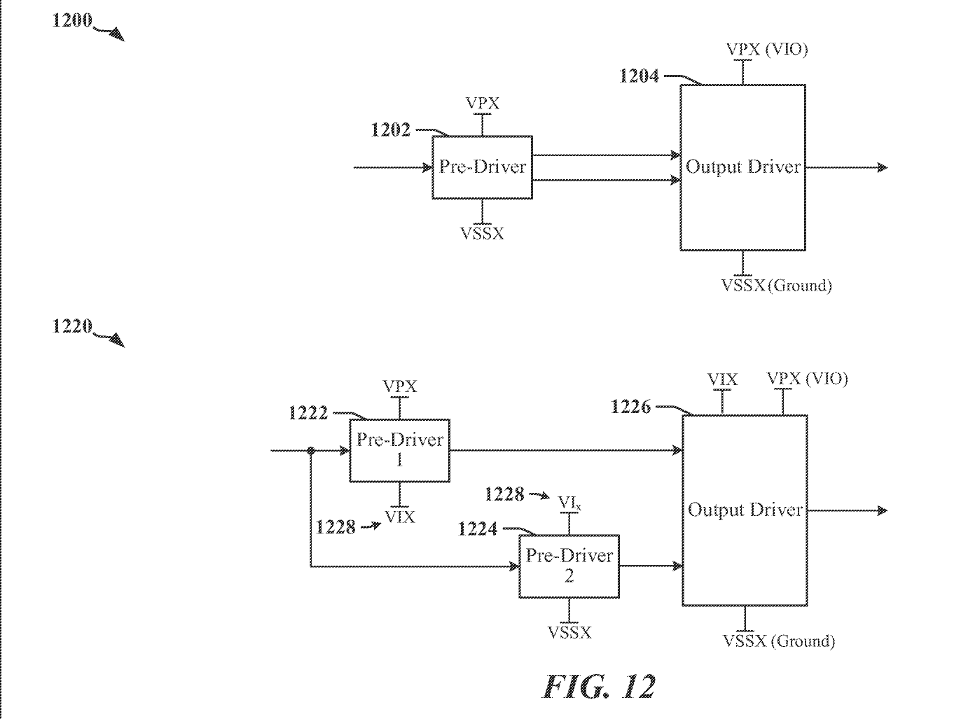

FIG. 12 includes diagrams 1200, 1220 that illustrate examples of circuits that may be implemented in an I/O pad circuit of a dual voltage-mode driver. The dual voltage-mode driver may be incorporated in the modem 202 or in an RF front-end device 212-216 (see FIG. 2), for example. In the first diagram 1200, a high voltage output driver 1204 may be used to support high-voltage mode operations. A pre-driver 1202 may provide control signals used to control the high voltage output driver 1204.

In the second diagram 1220, low voltage transistors 1226 may be used to support the lower VIO, with an intermediate supply 1228 mitigating over-voltage stress on the low voltage devices when operating under higher VIO. A first pre-driver 1222 may operate between VIO and the intermediate supply 1228, while a second pre-driver 1224 operates between the intermediate supply and VSSX. The use of the intermediate supply 1228 with low-voltage transistors can eliminate the need for calibration. Smaller process, voltage and temperature variations can be expected with the use of lower voltage transistors.

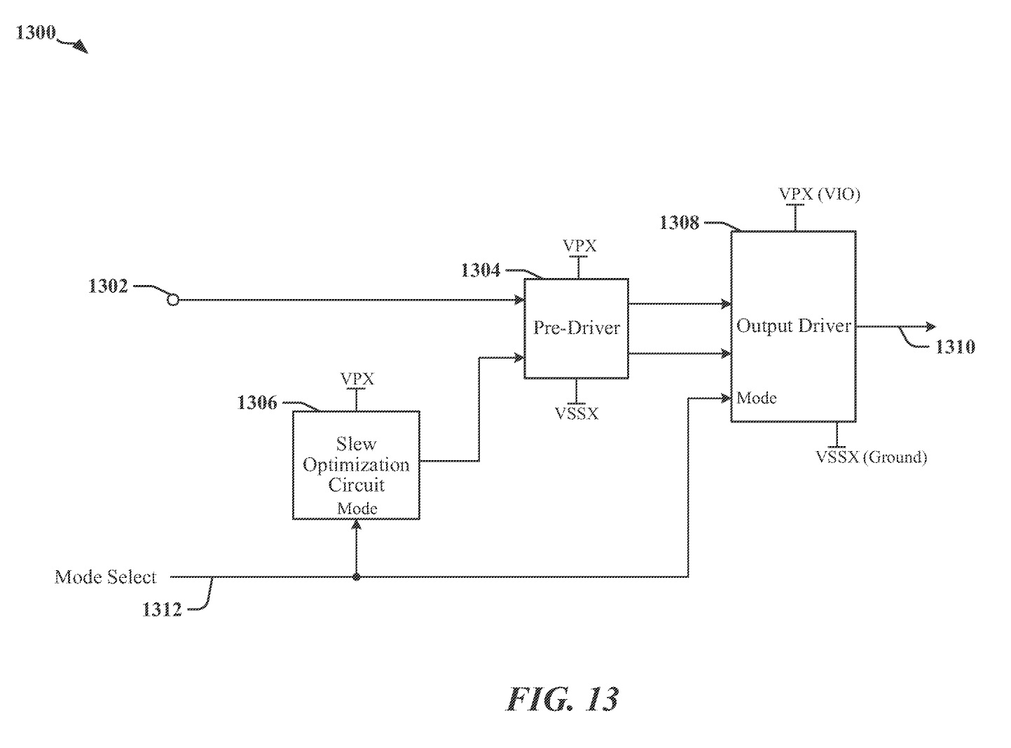

FIG. 13 includes a block diagram 1300 that illustrates an example of a circuit that may be implemented in an I/O pad circuit of a dual voltage-mode driver. The dual voltage-mode driver may be incorporated in the modem 202 or in an RF front-end device 212-216 (see FIG. 2), for example. A high-voltage output driver 1308 may be used to support high-voltage mode and low-voltage mode operations. A pre-driver 1304 may provide control signals used to control the high-voltage output driver 1308. A mode select signal 1312, a register setting, or other parameter may configure the I/O pad circuit for a desired voltage mode. A slew optimization circuit 1306 may be used to control the slew rate of the output signal 1310 based on the voltage mode selected. The use of a slew optimization circuit 1306 and high-voltage output driver 1308 can limit circuit changes to the I/O pad circuit, with minimal impact on system implementation and cost.

According to certain aspects, a common slew rate provides a faster rise/fall time for lower voltage support. A faster rise/fall can result in less impact from variations due to process, temperature and voltage. A faster rise/fall can result in better jitter performance. Consequently, the implementation of common slew rate can avoid complex and complicated circuit implementation in order to support lower VIO voltage.

Examples of Processing Circuits and Methods

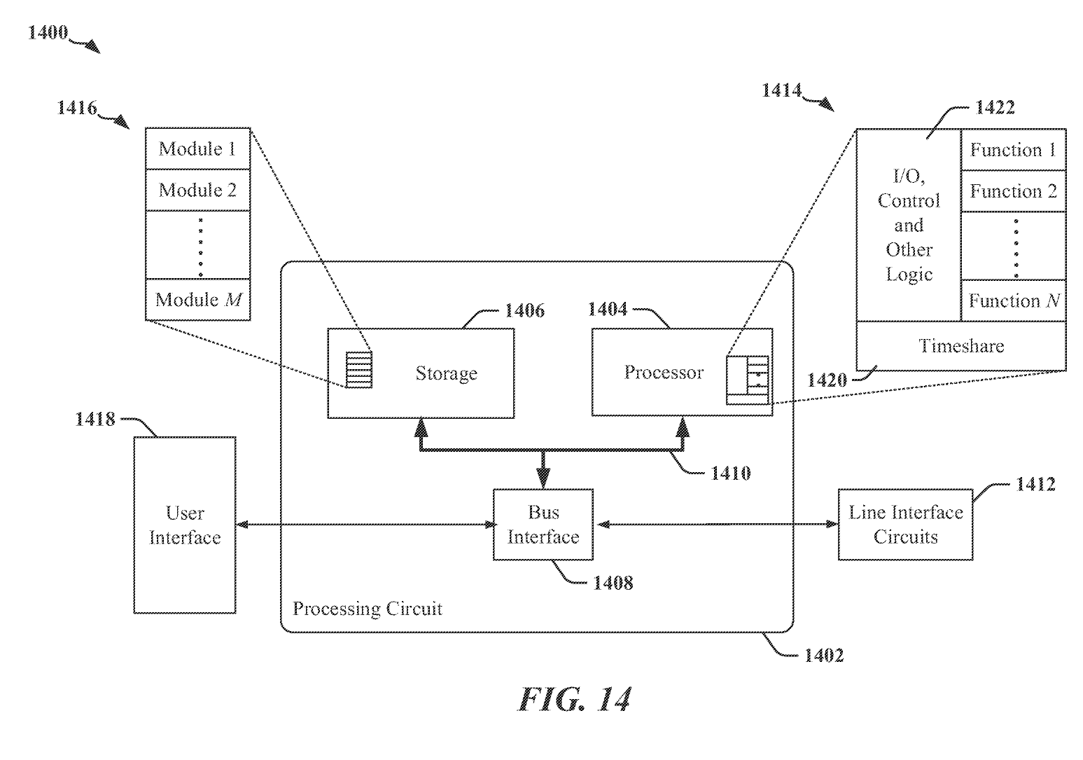

FIG. 14 is a conceptual diagram illustrating a simplified example of a hardware implementation for an apparatus 1400 employing a processing circuit 1402 that may be configured to perform one or more functions disclosed herein. In accordance with various aspects of the disclosure, an element, or any portion of an element, or any combination of elements as disclosed herein may be implemented using the processing circuit 1402. The processing circuit 1402 may include one or more processors 1404 that are controlled by some combination of hardware and software modules. Examples of processors 1404 include microprocessors, microcontrollers, digital signal processors (DSPs), ASICs, field programmable gate arrays (FPGAs), programmable logic devices (PLDs), state machines, sequencers, gated logic, discrete hardware circuits, and other suitable hardware configured to perform the various functionality described throughout this disclosure. The one or more processors 1404 may include specialized processors that perform specific functions, and that may be configured, augmented or controlled by one of the software modules 1416. The one or more processors 1404 may be configured through a combination of software modules 1416 loaded during initialization, and further configured by loading or unloading one or more software modules 1416 during operation.

In the illustrated example, the processing circuit 1402 may be implemented with a bus architecture, represented generally by the bus 1410. The bus 1410 may include any number of interconnecting buses and bridges depending on the specific application of the processing circuit 1402 and the overall design constraints. The bus 1410 links together various circuits including the one or more processors 1404, and storage 1406. Storage 1406 may include memory devices and mass storage devices, and may be referred to herein as computer-readable media and/or processor-readable media. The bus 1410 may also link various other circuits such as timing sources, timers, peripherals, voltage regulators, and power management circuits. A bus interface 1408 may provide an interface between the bus 1410 and one or more transceivers 1412. A transceiver 1412 may be provided for each networking technology supported by the processing circuit. In some instances, multiple networking technologies may share some or all of the circuitry or processing modules found in a transceiver 1412. Each transceiver 1412 provides a means for communicating with various other apparatus over a transmission medium. Depending upon the nature of the apparatus 1400, a user interface 1418 (e.g., keypad, display, speaker, microphone, joystick) may also be provided, and may be communicatively coupled to the bus 1410 directly or through the bus interface 1408.

A processor 1404 may be responsible for managing the bus 1410 and for general processing that may include the execution of software stored in a computer-readable medium that may include the storage 1406. In this respect, the processing circuit 1402, including the processor 1404, may be used to implement any of the methods, functions and techniques disclosed herein. The storage 1406 may be used for storing data that is manipulated by the processor 1404 when executing software, and the software may be configured to implement any one of the methods disclosed herein.

One or more processors 1404 in the processing circuit 1402 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the storage 1406 or in an external computer readable medium. The external computer-readable medium and/or storage 1406 may include a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium and/or storage 1406 may also include, by way of example, a carrier wave, a transmission line, and any other suitable medium for transmitting software and/or instructions that may be accessed and read by a computer. Computer-readable medium and/or the storage 1406 may reside in the processing circuit 1402, in the processor 1404, external to the processing circuit 1402, or be distributed across multiple entities including the processing circuit 1402. The computer-readable medium and/or storage 1406 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

The storage 1406 may maintain software maintained and/or organized in loadable code segments, modules, applications, programs, etc., which may be referred to herein as software modules 1416. Each of the software modules 1416 may include instructions and data that, when installed or loaded on the processing circuit 1402 and executed by the one or more processors 1404, contribute to a run-time image 1414 that controls the operation of the one or more processors 1404. When executed, certain instructions may cause the processing circuit 1402 to perform functions in accordance with certain methods, algorithms and processes described herein.

Some of the software modules 1416 may be loaded during initialization of the processing circuit 1402, and these software modules 1416 may configure the processing circuit 1402 to enable performance of the various functions disclosed herein. For example, some software modules 1416 may configure internal devices and/or logic circuits 1422 of the processor 1404, and may manage access to external devices such as the transceiver 1412, the bus interface 1408, the user interface 1418, timers, mathematical coprocessors, and so on. The software modules 1416 may include a control program and/or an operating system that interacts with interrupt handlers and device drivers, and that controls access to various resources provided by the processing circuit 1402. The resources may include memory, processing time, access to the transceiver 1412, the user interface 1418, and so on.

One or more processors 1404 of the processing circuit 1402 may be multifunctional, whereby some of the software modules 1416 are loaded and configured to perform different functions or different instances of the same function. The one or more processors 1404 may additionally be adapted to manage background tasks initiated in response to inputs from the user interface 1418, the transceiver 1412, and device drivers, for example. To support the performance of multiple functions, the one or more processors 1404 may be configured to provide a multitasking environment, whereby each of a plurality of functions is implemented as a set of tasks serviced by the one or more processors 1404 as needed or desired. In one example, the multitasking environment may be implemented using a timesharing program 1420 that passes control of a processor 1404 between different tasks, whereby each task returns control of the one or more processors 1404 to the timesharing program 1420 upon completion of any outstanding operations and/or in response to an input such as an interrupt. When a task has control of the one or more processors 1404, the processing circuit is effectively specialized for the purposes addressed by the function associated with the controlling task. The timesharing program 1420 may include an operating system, a main loop that transfers control on a round-robin basis, a function that allocates control of the one or more processors 1404 in accordance with a prioritization of the functions, and/or an interrupt driven main loop that responds to external events by providing control of the one or more processors 1404 to a handling function.

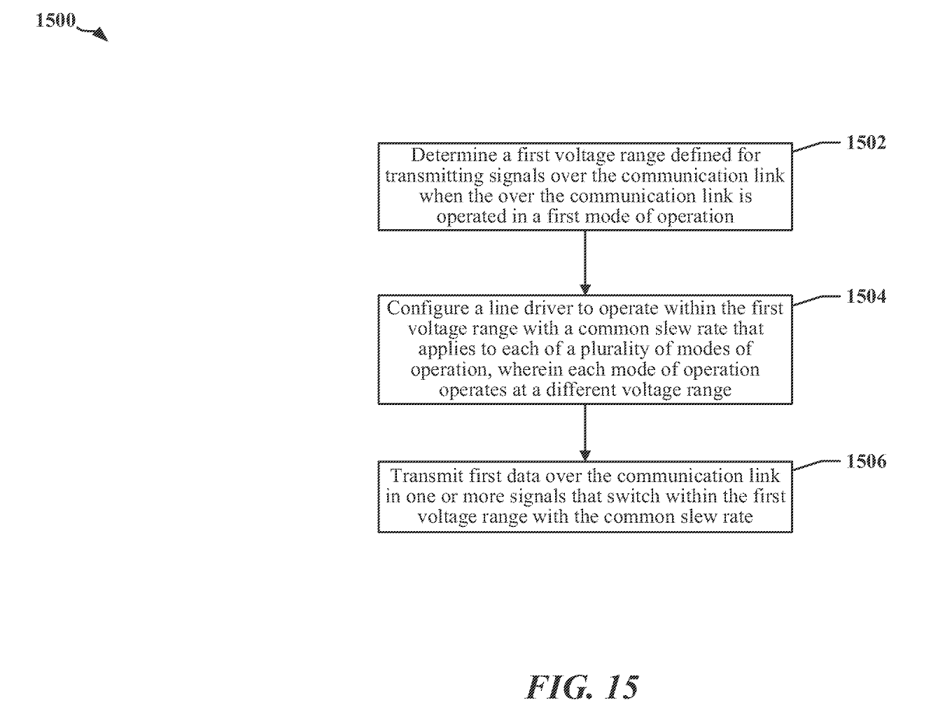

FIG. 15 is a flow chart 1500 of a method for controlling transmissions by a device coupled to a data communication link In one example, the method may be performed at a master device coupled to the data communication link In another example, the method may relate to a high-speed I/O pad incorporated in a modem 202 (see FIG. 2). In another example, the method may relate to a high-speed I/O pad incorporated in an RF front-end device 212-216. In various example, the communication link may be an RFFE bus.

At block 1502, the device may determine a first voltage range defined for transmitting signals over the communication link when the over the communication link is operated in a first mode of operation.

At block 1504, the device may configure a line driver to operate within the first voltage range with a common slew rate that applies to each of a plurality of modes of operation. Each mode of operation may define a different voltage range for transmitting signals on the communication link.

At block 1506, the device may transmit first data over the communication link in one or more signals that switch within the first voltage range with the common slew rate.

In various examples, configuring the line driver to operate within the first voltage range includes determining a rise time and a fall time for the line driver by applying a scaling factor to rise and fall times specified for a baseline mode of operation. The first voltage range may be 1.2 volts and a voltage range associated with the baseline mode of operation may be 1.8 volts. The first voltage range may be 1.0 volts and the voltage range associated with the baseline mode of operation may be 1.8 volts. The first voltage range may be 0.9 volts and the voltage range associated with the baseline mode of operation may be 1.8 volts. The first voltage range may be 1.0 volts and a voltage range associated with the baseline mode of operation may be 1.2 volts. The first voltage range may be 0.9 volts and a voltage range associated with the baseline mode of operation may be 1.2 volts. The first voltage range may be any suitable range of voltages for a given baseline voltage mode of operation. Determining rise time and fall time for the line driver may include reducing the rise time and the fall time within a range calculated to avoid violating electromagnetic interference limits for radio frequency harmonics in a frequency band associated with the communication link.

In one example, configuring the line driver to operate within the first voltage range includes determining an operating point characterizing PVT conditions, and adjusting an output setting of the line driver based on the PVT conditions. The output setting may configure transition times for the one or more signals.

In another example, configuring the line driver to operate within the first voltage range includes configuring a high voltage circuit of the line driver to switch within the first voltage range when the first voltage range is lower than a rated voltage range for the high voltage circuit.

In another example, configuring the line driver to operate within the first voltage range includes configuring transition times for the one or more signals using a slew optimization circuit.

In some examples, the device may configure the line driver to operate within a second voltage range corresponding to a second mode of operation, the second voltage range being different from the first voltage range, and transmit second data over the communication link in one or more signals that switch within the second voltage range with the common slew rate. Configuring the line driver to operate within the first voltage range may include determining transition times for the one or more signals by applying a scaling factor to rise and fall times specified for the second mode of operation. Configuring the line driver to operate within the first voltage range may include configuring a high voltage circuit of the line driver to switch within the first voltage range when the first voltage range is lower than the second voltage range and when the high voltage circuit is rated for the second voltage range. Configuring the line driver to operate within a selected mode of operation may include configuring transition times for the one or more signals using a slew optimization circuit.

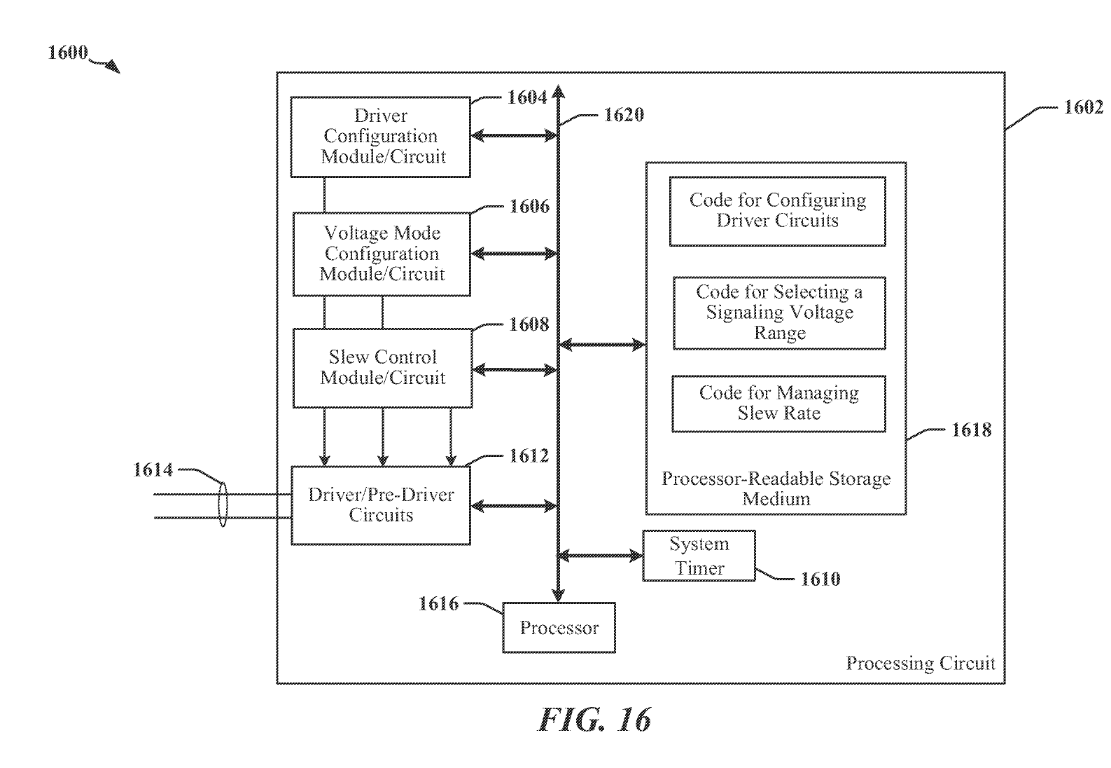

FIG. 16 is a diagram illustrating a simplified example of a hardware implementation for an apparatus 1600 employing a processing circuit 1602. The processing circuit typically has a processor 1616 that may include one or more of a microprocessor, microcontroller, digital signal processor, a sequencer and a state machine. The processing circuit 1602 may be implemented with a bus architecture, represented generally by the bus 1620. The bus 1620 may include any number of interconnecting buses and bridges depending on the specific application of the processing circuit 1602 and the overall design constraints. The bus 1620 links together various circuits including one or more processors and/or hardware modules, represented by the processor 1616, the modules or circuits 1604, 1606, 1608, one or more drivers 1612 configurable to support communication over connectors or wires of a data communication link 1614 and the computer-readable storage medium 1618. The bus 1620 may also link various other circuits such as timing sources, peripherals, voltage regulators, and power management circuits, which are well known in the art, and therefore, will not be described any further.

The processor 1616 is responsible for general processing, including the execution of software stored on the computer-readable storage medium 1618. The software, when executed by the processor 1616, causes the processing circuit 1602 to perform the various functions described supra for any particular apparatus. The computer-readable storage medium may also be used for storing data that is manipulated by the processor 1616 when executing software, including data decoded from symbols transmitted over the data communication link 1614, which may be configured to include data lanes and clock lanes. The processing circuit 1602 further includes at least one of the modules 1604, 1606, 1608, and 1610. The modules 1604, 1606, and 1608 may be software modules running in the processor 1616, resident/stored in the computer-readable storage medium 1618, one or more hardware modules coupled to the processor 1616, or some combination thereof. The modules 1604, 1606, and/or 1608 may include microcontroller instructions, state machine configuration parameters, or some combination thereof.

In one configuration, the apparatus 1600 includes a module and/or circuit 1604 that is configured to manage and operate a driver configuration for an I/O pad, a module and/or circuit 1606 configured to select a voltage range for the I/O pad and configure the one or more drivers 1612 for the voltage mode, and a module and/or circuit 1608 configured to control slew rate in signals output by the one or more drivers 1612.

The one or more drivers 1612 may include an output driver, at least one pre-driver circuit coupled to the output driver. The module and/or circuit 1608 configured to control slew rate may be adapted to configure transition times for an output signal provided by the output driver. The output driver may be operable in plurality of modes, each mode defining a different voltage range of the output signal. The output driver may be adapted such that transitions in the output signal have a common slew rate for each voltage range defined by the plurality of modes.

The module and/or circuit 1608 configured to control slew rate may include a compensation circuit configured to define a rise time and a fall time for the output signal by applying a scaling factor to rise and fall times specified for a baseline mode. In one example, the baseline mode defines a 1.2 volt voltage range for the output signal. In another example, the baseline mode defines a voltage range for the output signal that is less than 1.2 volts. In another example, the baseline mode defines a voltage range for the output signal that is greater than 1.2 volts.

The module and/or circuit 1608 configured to control slew rate may include a compensation circuit adapted to configure the output driver and the at least one pre-driver circuit based on PVT conditions.

The output driver may be rated to switch within a first voltage range, and the module and/or circuit 1608 configured to control slew rate may include a compensation circuit adapted to configure the output driver to switch within a second voltage range when the second voltage range is lower than the first voltage range. The output driver may be adapted to provide the common slew rate when the output driver switches within the first voltage range and when the output driver switches within the second voltage range.

In some examples, the output driver resides in a baseband modem. In some examples, the output driver resides in a radio-frequency front-end device.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A method for controlling transmissions by a device coupled to a communication link, comprising:
determining a first voltage range defined for transmitting signals over the communication link when the communication link is operated in a first mode of operation;
configuring a line driver to operate within the first voltage range with a common slew rate that applies to each of a plurality of modes of operation, each mode of operation defining a different voltage range for transmitting signals on the communication link; and
transmitting first data over the communication link in one or more signals that switch within the first voltage range with the common slew rate.

2. The method of claim 1, wherein configuring the line driver to operate within the first voltage range comprises:
determining a rise time and a fall time for the line driver by applying a scaling factor to rise and fall times specified for a baseline mode of operation.

3. The method of claim 2, wherein the first voltage range is 1.2 volts and a voltage range associated with the baseline mode of operation is 1.8 volts.

4. The method of claim 2, wherein the first voltage range is 1.0 volts and a voltage range associated with the baseline mode of operation is 1.8 volts.

5. The method of claim 2, wherein the first voltage range is 0.9 volts and a voltage range associated with the baseline mode of operation is 1.8 volts.

6. The method of claim 2, wherein the first voltage range is 1.0 volts and a voltage range associated with the baseline mode of operation is 1.2 volts.

7. The method of claim 2, wherein the first voltage range is 0.9 volts and a voltage range associated with the baseline mode of operation is 1.2 volts.

8. The method of claim 2, wherein determining a rise time and a fall time for the line driver comprises:
reducing the rise time and the fall time within a range calculated to avoid violating electromagnetic interference limits for radio frequency harmonics in a frequency band associated with the communication link.

9. The method of claim 1, wherein configuring the line driver to operate within the first voltage range comprises:
determining an operating point characterizing process, voltage and temperature (PVT) conditions; and
adjusting an output setting of the line driver based on the PVT conditions, wherein the output setting configures transition times for the one or more signals.

10. The method of claim 1, wherein configuring the line driver to operate within the first voltage range comprises:
configuring a high voltage circuit of the line driver to switch within the first voltage range when the first voltage range is lower than a rated voltage range for the high voltage circuit.

11. The method of claim 1, wherein configuring the line driver to operate within the first voltage range comprises:
configuring transition times for the one or more signals using a slew optimization circuit.

12. The method of claim 1, and further comprising:
configuring the line driver to operate within a second voltage range corresponding to a second mode of operation, the second voltage range being different from the first voltage range; and
transmitting second data over the communication link in one or more signals that switch within the second voltage range with the common slew rate.

13. The method of claim 12, wherein configuring the line driver to operate within the first voltage range comprises:
determining transition times for the one or more signals by applying a scaling factor to rise and fall times specified for the second mode of operation.

14. The method of claim 12, wherein configuring the line driver to operate within the first voltage range comprises:
configuring a high voltage circuit of the line driver to switch within the first voltage range when the first voltage range is lower than the second voltage range and when the high voltage circuit is rated for the second voltage range.

15. The method of claim 12, wherein configuring the line driver to operate within a selected mode of operation comprises:
configuring transition times for the one or more signals using a slew optimization circuit.

16. An apparatus, comprising:
an output driver;
at least one pre-driver circuit coupled to the output driver; and
a slew rate control circuit adapted to configure transition times for an output signal provided by the output driver,
wherein the output driver is operable in plurality of modes, each mode defining a different voltage range of the output signal, and
wherein the output driver is adapted such that transitions in the output signal have a common slew rate for each voltage range defined by the plurality of modes.

17. The apparatus of claim 16, and further comprising:
a compensation circuit configured to define a rise time and a fall time for the output signal by applying a scaling factor to rise and fall times specified for a baseline mode.

18. The apparatus of claim 17, wherein the baseline mode defines a 1.2 volt voltage range for the output signal.

19. The apparatus of claim 17, wherein the baseline mode defines a voltage range for the output signal that is less than 1.2 volts.

20. The apparatus of claim 17, wherein the baseline mode defines a voltage range for the output signal that is greater than 1.2 volts.

21. The apparatus of claim 16, and further comprising:
a compensation circuit adapted to configure the output driver and the at least one pre-driver circuit based on process, voltage and temperature (PVT) conditions.

22. The apparatus of claim 16, wherein the output driver is rated to switch within a first voltage range, and further comprising:
a compensation circuit adapted to configure the output driver to switch within a second voltage range when the second voltage range is lower than the first voltage range,
wherein the output driver is adapted to provide the common slew rate when the output driver switches within the first voltage range and when the output driver switches within the second voltage range.

23. The apparatus of claim 16, wherein the output driver resides in a baseband modem.

24. The apparatus of claim 16, wherein the output driver resides in a radio-frequency front-end device.

25. A storage medium comprising code for:
determining a first voltage range defined for transmitting signals over a communication link when the communication link is operated in a first mode of operation;
configuring a line driver to operate within the first voltage range with a common slew rate that applies to each of a plurality of modes of operation, each mode of operation defining a different voltage range for transmitting signals on the communication link; and
transmitting first data over the communication link in one or more signals that switch within the first voltage range with the common slew rate.

26. The storage medium of claim 25 and comprising code for:
determining transition times for the one or more signals by applying a scaling factor to rise and fall times specified for a second mode of operation.

27. The storage medium of claim 25 and comprising code for:
determining a rise time and a fall time for the line driver by applying a scaling factor to rise and fall times specified for a baseline mode of operation.

28. The storage medium of claim 25 and comprising code for:
determining an operating point characterizing process, voltage and temperature (PVT) conditions; and
adjusting an output setting of the line driver based on the PVT conditions, wherein the output setting configures transition times for the one or more signals.

29. The storage medium of claim 25 and comprising code for:
configuring a high voltage circuit of the line driver to switch within the first voltage range when the first voltage range is lower than a rated voltage range for the high voltage circuit.

30. The storage medium of claim 25 and comprising code for:
configuring transition times for the one or more signals using a slew optimization circuit.
